(19) United States
(12) Patent Application Publication
(10) Pub. No.: US 2015/0016069 A1
(43) Pub. Date: Jan. 15, 2015

(54) PRINTED CIRCUIT BOARD

(71) Applicant: Shenzhen China Star Optoelectronics Technology Co. Ltd., Shenzhen, Guangdong (CN)

(72) Inventors: Jianyong Fu, Shenzhen (CN); Anle Hu, Shenzhen (CN); Xiaoping Tan, Shenzhen (CN)

(73) Assignee: Shenzhen China Star Optoelectronics Technology Co., Ltd., Shenzhen, Guangdong (CN)

(21) Appl. No.: 14/004,443

(22) PCT Filed: Jul. 15, 2013
(86) PCT No.: PCT/CN2013/079397

§ 371 Date: Sep. 11, 2013

(30) Foreign Application Priority Data
Jul. 9, 2013 (CN) 201310286891.7

(51) Int. Cl. H05K 1/02

(52) U.S. Cl. CPC H05K 1/0201; H05K 1/0271
USPC 361/748; 174/257

(57) ABSTRACT

A printed circuit board (PCB) is disclosed. The PCB includes a main body. A first surface of the main body is a connecting surface for electrical components. A second surface of the main body is a conductive cooper foil layer operating as ground wires. A plurality of grooves is arranged on the conductive cooper foil layer. The grooves pass through the conductive cooper foil layer to connect to the main body of the PCB. The thermal stress generated in the PCB welding process can be effectively released via the grooves. The inflation of the conductive cooper coil is relieved such that the PCB is prevented from being wrapped or cooper bubbling. In this way, the operation efficiency is enhanced and the manufacturing cost is reduced.

### BACKGROUND OF THE INVENTION

1. Field of the Invention

The present disclosure relates to printed circuit board (PCB) technology, and more particularly to a PCB for preventing the circuit boards from being warped due to poor heat dissipation.

2. Discussion of the Related Art

PCB plays is a key component for electrical devices. The PCB is a supporting body for electrical components. In addition, the PCB provides the lines for connecting other electrical components. The PCBs not only fix different electrical components thereon, but also provide electrical connections for the electrical components. With the development of the electrical devices, there are more and more electrical components needed to be arranged on the PCB, and thus the density of the electrical components and the lines grows at the same time.

In order to reduce the cost, the PCBs may be compressed on one board including a connecting surface for the electrical components at a first side and a ground wire module made by conductive copper foil at a second side. PCB warping or cooper bubbling may occur due to thermal stress such that the electrical components cannot be assembled or imperfect contact happens between the electrical components and solder joints in the surface mounted technology (SMT) process. Under the circumstance, a portion of the substrate cannot contact the pad, and thus tin cannot be soldered onto the soldering surface of the substrate. In order to overcome the above problem, wrapped PCBs may be arranged within a compressed machine and a cold pressing process is applied to the PCBs for several hours or more than ten hours. However, after the above process, the PCBs may not be flat enough. On the other hand, the PCBs are prone to be warped again.

### SUMMARY

The object of the invention is to provide a PCB for preventing the circuit boards from being warped due to poor heat dissipation.

In one aspect, a PCB includes: a main body, a first surface of the main body is a connecting surface for electrical components, a second surface of the main body is a conductive cooper foil layer operating as ground wires, and wherein a plurality of grooves are arranged on the conductive cooper foil layer.

Wherein the grooves are arranged in an array form.

Wherein the grooves pass through the conductive cooper foil layer.

Wherein the grooves are substantially square-shaped or circular-shaped.

Wherein the diameter of the circular-shaped groove is in a range between 1 and 3 mm.

Wherein a side length of the square-shaped grooves is in a range between 1 and 3 mm.

Wherein the grooves are substantially square-shaped or circular-shaped.

Wherein the diameter of the circular-shaped groove is in a range between 1 and 3 mm.

Wherein a side length of the square-shaped grooves is in a range between 1 and 3 mm.

In another aspect, an electronic device, includes: a PCB and at least one electronic components connecting to a first surface of a main body of the PCB, a second surface of the main body is a conductive cooper foil layer operating as ground wires, and wherein a plurality of grooves are arranged on the conductive cooper foil layer.

Wherein the grooves are arranged in an array form.

Wherein the grooves pass through the conductive cooper foil layer.

Wherein the grooves are substantially square-shaped or circular-shaped.

Wherein the diameter of the circular-shaped groove is in a range between 1 and 3 mm.

Wherein a side length of the square-shaped grooves is in a range between 1 and 3 mm.

Wherein the grooves are substantially square-shaped or circular-shaped.

Wherein the diameter of the circular-shaped groove is in a range between 1 and 3 mm.

Wherein a side length of the square-shaped grooves is in a range between 1 and 3 mm.

In view of the above, a plurality of grooves is arranged on the conductive cooper foil layer of the PCB. The grooves pass through the conductive cooper foil layer to connect to the main body of the PCB. The thermal stress generated in the PCB welding process can be effectively released via the grooves. The inflation of the conductive cooper coil is relieved such that the PCB is prevented from being wrapped or cooper bubbling. In this way, the operation efficiency is enhanced and the manufacturing cost is reduced.

### BRIEF DESCRIPTION OF THE DRAWINGS

FIG. 1 is a schematic view of a PCB in accordance with one embodiment.

FIG. 2 is a schematic view of a conductive cooper foil layer including a plurality of grooves in accordance with one embodiment.

FIG. 2 is a schematic view of a conductive cooper foil layer including a plurality of grooves in accordance with another embodiment.

### DETAILED DESCRIPTION OF THE EMBODIMENTS

Embodiments of the invention will now be described more fully hereinafter with reference to the accompanying drawings, in which embodiments of the invention are shown.

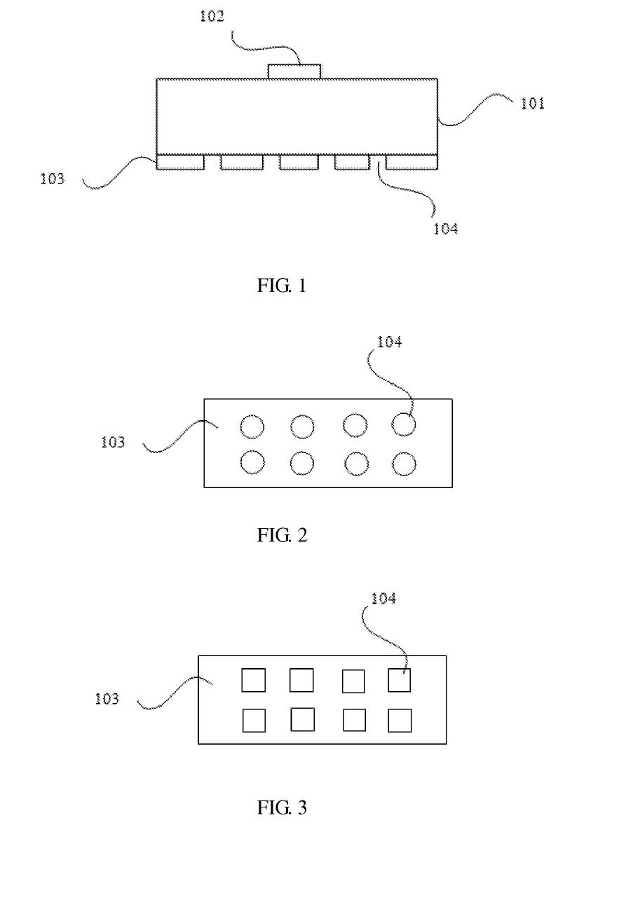

FIG. 1 shows the PCB including a main body 101. A first surface of the main body 101 is a connecting surface for the electrical components 102. A second surface of the main body 101 connects with a conductive cooper foil layer 103 operating as ground wires. The conductive cooper foil layer 103 includes a plurality of grooves 104 passing through the conductive cooper foil layer 103 to connect to the main body 101.

As shown in FIG. 2, the grooves 104 are substantially circular-shaped with a diameter in a range between 1 and 3 mm. The grooves 104 are arranged in an array form on the conductive cooper foil layer 103.

Preferably, as shown in FIG. 3, the grooves 104 are substantially square-shaped with side length of a range between 1 and 3 mm.

It can be understood that the shape of the grooves 104 is not limited to the above-mentioned shapes. The shape of the grooves 104 may be prism, rectangular, oval, and so on. In addition, the dimension of the grooves may be configured according to the dimension of the PCB.

In view of the above, a plurality of grooves is arranged on the conductive cooper foil layer of the PCB. The grooves pass through the conductive cooper foil layer to connect to the main body of the PCB. The thermal stress generated in the PCB welding process can be effectively released via the grooves. The inflation of the conductive cooper coil is relieved such that the PCB is prevented from being wrapped or cooper bubbling. In this way, the operation efficiency is enhanced and the manufacturing cost is reduced.

It is believed that the present embodiments and their advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

What is claimed is:

1. A printed circuit board (PCB), comprising:
a main body, a first surface of the main body is a connecting surface for electrical components, a second surface of the main body is a conductive cooper foil layer operating as ground wires, and wherein a plurality of grooves are arranged on the conductive cooper foil layer.

2. The PCB as claimed in claim 1, wherein the grooves are arranged in an array form.

3. The PCB as claimed in claim 1, wherein the grooves pass through the conductive cooper foil layer.

4. The PCB as claimed in claim 1, wherein the grooves are substantially square-shaped or circular-shaped.

5. The PCB as claimed in claim 4, wherein the diameter of the circular-shaped groove is in a range between 1 and 3 mm.

6. The PCB as claimed in claim 4, wherein a side length of the square-shaped grooves is in a range between 1 and 3 mm.

7. The PCB as claimed in claim 2, wherein the grooves are substantially square-shaped or circular-shaped.

8. The PCB as claimed in claim 7, wherein the diameter of the circular-shaped groove is in a range between 1 and 3 mm.

9. The PCB as claimed in claim 7, wherein a side length of the square-shaped grooves is in a range between 1 and 3 mm.

10. An electronic device, comprising:
a PCB and at least one electronic components connecting to a first surface of a main body of the PCB, a second surface of the main body is a conductive cooper foil layer operating as ground wires, and wherein a plurality of grooves are arranged on the conductive cooper foil layer.

11. The electronic device as claimed in claim 10, wherein the grooves are arranged in an array form.

12. The electronic device as claimed in claim 10, wherein the grooves pass through the conductive cooper foil layer.

13. The electronic device as claimed in claim 10, wherein the grooves are substantially square-shaped or circular-shaped.

14. The electronic device as claimed in claim 13, wherein the diameter of the circular-shaped groove is in a range between 1 and 3 mm.

15. The electronic device as claimed in claim 13, wherein a side length of the square-shaped grooves is in a range between 1 and 3 mm.

16. The electronic device as claimed in claim 11, wherein the grooves are substantially square-shaped or circular-shaped.

17. The electronic device as claimed in claim 16, wherein the diameter of the circular-shaped groove is in a range between 1 and 3 mm.

18. The electronic device as claimed in claim 16, wherein a side length of the square-shaped grooves is in a range between 1 and 3 mm.
